(19) United States
(12) Patent Application Publication
(10) Pub. No.: US 2023/0309268 A1
(43) Pub. Date: Sep. 28, 2023

(54) FACIAL INTERFACE FOR GOGGLE

(71) Applicant: Saritek Technical Solutions Inc. dba Alpatronix, Anaheim, CA (US)

(72) Inventor: Reza Alipanah Jahroudi, Irvine, CA (US)

(21) Appl. No.: 18/188,928

(22) Filed: Mar. 23, 2023

Related U.S. Application Data
(60) Provisional application No. 63/323,267, filed on Mar. 24, 2022.

(51) Int. Cl. H05K 7/20; G06F 1/20; G02B 27/01

(52) U.S. Cl. CPC H05K 7/2039; G06F 1/203; G02B 27/0176

(57) ABSTRACT

A facial interface for a goggle including a cooling layer comprising a cooling substance. In some configurations, the cooling substance is configured to be cooled in a refrigerator or freezer to a suitable temperature and to absorb heat for a period of time after removal from the refrigerator or freezer. The facial interface also includes an external layer comprising a user-contacting surface configured to contact the face of a user. The facial interface is configured to be positioned between the goggle and the face of the user.

### INCORPORATION BY REFERENCE TO ANY PRIORITY APPLICATIONS

Any and all applications for which a foreign or domestic priority claim is identified in the Application Data Sheet as filed with the present application are hereby incorporated by reference herein in their entireties and made a part of the present disclosure.

### BACKGROUND

### Field

The present disclosure generally relates to goggles, such as virtual reality (VR) goggles, safety goggles, motorcycle/skiing goggles, or other types of goggles. In particular, the present disclosure relates to a facial interface for goggles.

### Description of the Related Art

Facial interfaces exist for goggles, including VR goggles. However, a need still exists for facial interfaces that provide improved performance, comfort, fit or simply provide the public with a useful choice.

### SUMMARY

The systems, methods and devices described herein have innovative aspects, no single one of which is indispensable or solely responsible for their desirable attributes. Without limiting the scope of the claims, some of the advantageous features will now be summarized.

An aspect of the present disclosure involves a facial interface for a goggle. The facial interface includes a body defining a user-contacting surface configured to contact the face of a user. The facial interface also includes the body comprises a cooling agent configured to absorb heat from the user along the user-contacting surface for a period of time. The facial interface is configured to be positioned between the goggle and the face of the user.

In some configurations, the period of time is at least fifteen (15) minutes.

In some configurations, the facial interface is provided in combination with a frame configured to support the facial interface.

In some configurations, the frame is removably connectable to the goggle.

In some configurations, the cooling agent is contained in a discrete layer.

In some configurations, the facial interface includes a cushioning layer.

In some configurations, the cooling agent is contained in a discrete layer, and the cooling layer is positioned closer to the user-contacting surface than the cushioning layer.

An aspect of the present disclosure involves a facial interface for a goggle. The facial interface includes a cooling layer comprising a cooling substance configured to be cooled in a cold environment and to absorb heat for a period of time after removal from the cold environment. The facial interface also includes an outer layer comprising a user-contacting surface configured to contact the face of a user. The facial interface is configured to be positioned between the goggle and the face of the user.

In some configurations, the facial interface comprises a closed loop or an open loop.

In some configurations, the facial interface includes at least one cushioning layer.

In some configurations, the cooling layer is located closer to the user-contacting surface than the cushioning layer.

In some configurations, the at least one cushioning layer comprises a first cushioning layer and a second cushioning layer.

In some configurations, the period of time is at least fifteen (15) minutes.

In some configurations, the outer layer comprises a first portion and a second portion joined at a seam.

In some configurations, the seam comprises a minimum width of at least about one (1) mm.

In some configurations, at least a portion of the facial interface defines an overall thickness of at least five (5) mm.

In some configurations, the cooling layer comprises a majority of a volume of the facial interface.

In some configurations, the facial interface is provided in combination with a frame configured to support the facial interface.

In some configurations, a connector is configured to connect the facial interface to the frame.

In some configurations, the connector comprises a hook-and-loop fastener.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are not to be considered limiting of its scope, the disclosure will be described with additional specificity and detail through the use of the accompanying drawings.

FIG. 1 is a perspective view of a VR goggle having a removable frame and a facial interface coupled to the frame.

FIG. 2 is a perspective exploded view of the facial interface and the frame shown separated from one another.

FIG. 3 is a rear view of the frame and facial interface in an assembled condition.

FIG. 4 is a rear view of the frame with the facial interface removed.

FIG. 5a is a sectional view of the facial interface.

FIG. 5b is a sectional view of an alternative version of the facial interface.

FIG. 6 is a rear view of the facial interface.

FIG. 7 is a front view of the facial interface.

FIG. 8 is a top view of the facial interface.

FIG. 9 is a bottom view of the facial interface.

FIG. 10 is a front perspective view of the facial interface.

FIG. 11 is a first side view of the facial interface.

FIG. 12 is a second side view of the facial interface.

### DETAILED DESCRIPTION

Embodiments of systems, components and methods of assembly and manufacture will now be described with reference to the accompanying figures, wherein like numerals refer to like or similar elements throughout. Although several embodiments, examples and illustrations are disclosed below, it will be understood by those of ordinary skill in the art that the inventions described herein extends beyond the specifically disclosed embodiments, examples and illustrations, and can include other uses of the inventions and obvious modifications and equivalents thereof. The terminology used in the description presented herein is not intended to be interpreted in any limited or restrictive manner simply because it is being used in conjunction with a detailed description of certain specific embodiments of the inventions. In addition, embodiments of the inventions can comprise several novel features and no single feature is solely responsible for its desirable attributes or is essential to practicing the inventions herein described.

Certain terminology may be used in the following description for the purpose of reference only, and thus are not intended to be limiting. For example, terms such as “above” and “below” refer to directions in the drawings to which reference is made. Terms such as “front,” “back,” “left,” “right,” “rear,” and “side” describe the orientation and/or location of portions of the components or elements within a consistent but arbitrary frame of reference which is made clear by reference to the text and the associated drawings describing the components or elements under discussion. Moreover, terms such as “first,” “second,” “third,” and so on may be used to describe separate components. Such terminology may include the words specifically mentioned above, derivatives thereof, and words of similar import.

The disclosed facial interface is configured to be positioned between a goggle and the face of a user of the goggle. In some configurations, the facial interface is configured to provide a cooling effect to the user of the goggle. The facial interface can be separate from or integrated with the goggle. In some configurations, the facial interface can be selectively connectable to the goggle. In some configurations, the facial interface is selectively connectable to the goggle through a frame. In such configurations, the frame can be permanently or removably connected to the goggle. In some configurations, the facial interface can provide greater comfort for the user in comparison to the original interface of the goggle. In some configurations, the facial interface can provide a different fit in comparison to the original interface of the goggle.

In some configurations, the facial interface includes a cooling agent, such as but not limited to a gel or liquid. In some configurations, the cooling agent can be “charged” or cooled in a cold environment. In some configurations, the chemical structure of the cooling agent is configured such that it does not become solid when placed in a cold environment (e.g., a refrigerator or freezer). As used herein, the term “cold environment” means an environment having a temperature of less than about five (5) degrees Celsius. It may be preferable to “recharge” the cooling agent of the facial interface at a lower temperature, such as a food storage freezer having a temperature of below freezing or a temperature at or below about zero (0) degrees Celsius or at or below about minus fifteen (−15) or minus twenty (−20) degrees Celsius. The cooling agent can be or comprise any substance suitable for use in or commonly used in a reusable cold pack or ice pack, such as water and/or a refrigerant gel or liquid. Preferably, the cooling agent is configured to be conformable when cold or below freezing (0 degrees Celsius or 32 degrees Fahrenheit) such that the facial interface remains conformable for comfort and to conform to the shape of the goggle. Such gel cold packs are often made of non-toxic materials that will remain a slow-flowing gel, and therefore will not spill easily or cause contamination in the event of a leak. A cooling agent may comprise water with a preservative and/or a gelling agent. For example, a cooling agent may be made by adding one or more of hydroxyethyl cellulose, sodium polyacrylate, or vinyl-coated silica gel to water or another liquid base. Ethylene glycol or propylene glycol could also be used. In some configurations, the cooling agent may be primarily water (e.g., equal to or greater than 95%—such as 99%) with a small amount of sodium polyacrylate (e.g., equal to or less than 5%—such as 1%). Other natural or artificial substances that exhibit the same or similar qualities can also be used. Facial interfaces constructed with such cooling agents can be reusable. In some configurations, the cooling agent may be chemically activated by an endothermic reaction. Such a cooling agent may comprise water and an activation agent, such as ammonium nitrate, calcium nitrate, or urea. The water and activation agent are kept separate until the time of use, such as by an internal barrier that can be broken by manipulation of the facial interface. Not all chemicals of a suitable nature for use as a cooling agent are listed herein, but it is contemplated that any suitable substance capable of acting as a cooling agent can be used with the disclosed facial interfaces.

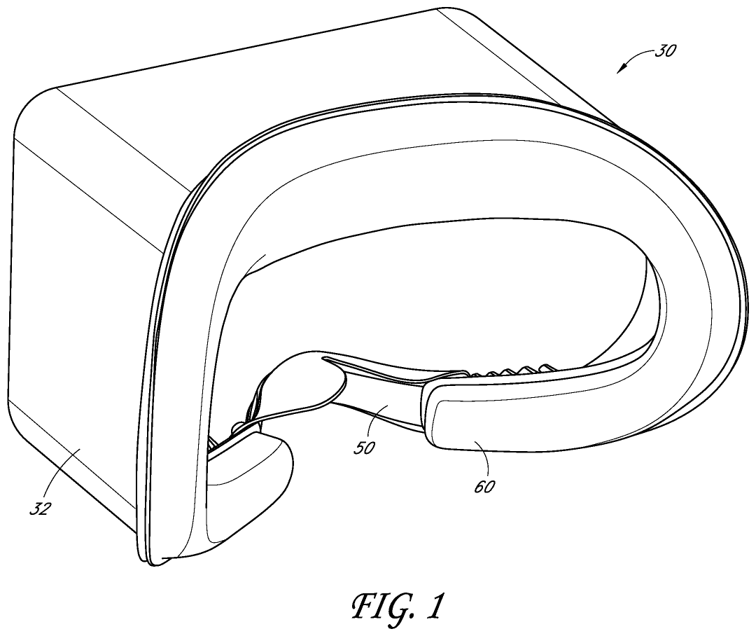

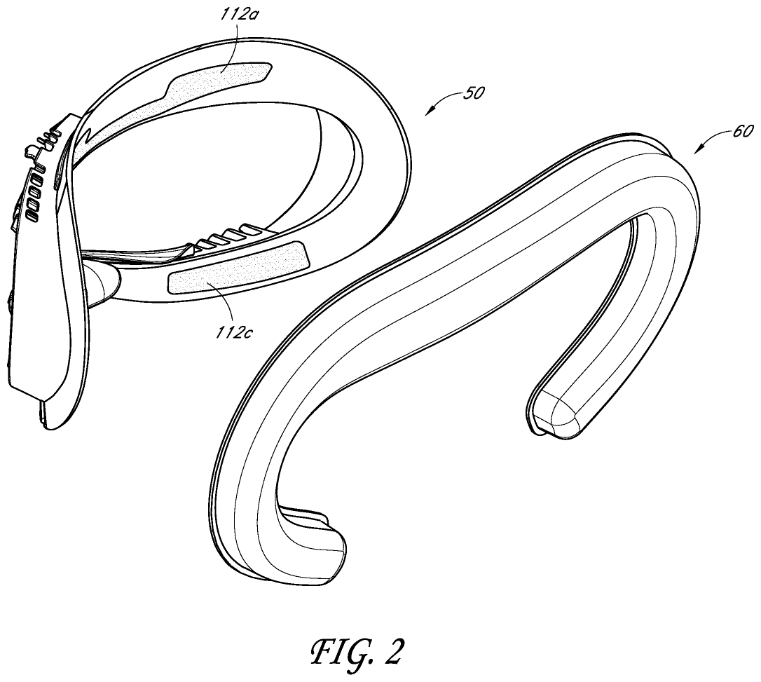

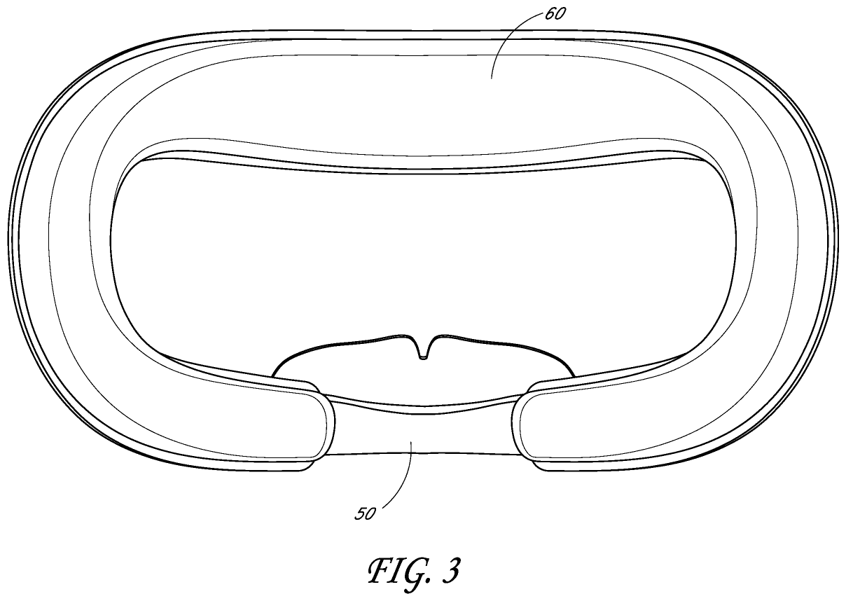

FIG. 1 illustrates a goggle 30 in the form of a virtual reality (VR) goggle. With additional reference to FIGS. 2-4, the VR goggle 30 includes a body 32, a frame 50, and a facial interface 60 attached to or otherwise supported by the frame 50. The illustrated facial interface 60 is configured to provide a cooling effect to a user of the goggle 30. Although the facial interface 60 is described with reference to an embodiment configured for use with VR goggles, it is contemplated that the facial interface 60 can be used with other types of goggles. Accordingly, references to VR goggles herein can refer to all types of goggles unless indicated otherwise either explicitly or by context.

In the illustrated arrangement, the frame 50 is a hard plastic frame that attaches to or forms a part of the VR goggle 30. The illustrated facial interface 60 is or comprises a soft cushion to act as a comfortable intermediary between the plastic frame 50 and the user's face. In some configurations, the facial interface 60 is removable from the frame 50. The facial interface 60 can be conveniently removable from and replaceable to the frame 50. Such an arrangement can allow for simple and convenient refreshing of the facial interface 60 as described further herein.

Embodiments of the present disclosure involve the soft cushion or facial interface 60 component, which can be provided as a substitute to the original cushion that is provided with the VR goggle 30. In some configurations, the facial interface 60 and the frame 50 can be provided as a substitute to the original cushion and/or frame of the VR goggle 30. The illustrated facial interface 60 includes a cooling element or cooling substance that provides a cooling effect or a perception of cold to the user of the interface 60 and associated VR goggle 30. The cooling element or cooling substance can provide a cooling effect by increasing a transfer of heat from the skin of the user that is in contact with or close to the facial interface 60 relative to the transfer of heat that would occur with a conventional facial interface or in the absence of an interface. The facial interface 60 can provide a cooling effect by having a temperature that is less than room temperature for a period of time. In some configurations, the facial interface 60 can maintain a temperature of less than about twenty (20) or twenty-one (21) degrees Celsius for a period of time.

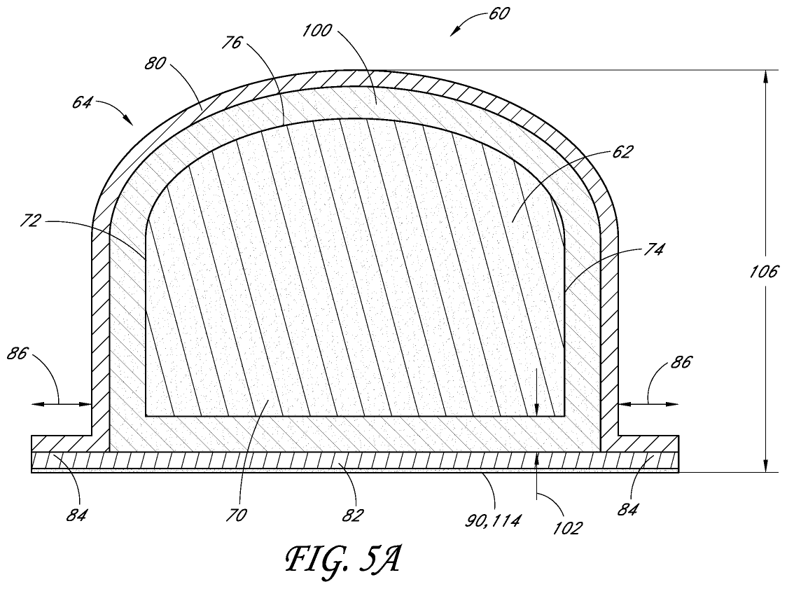

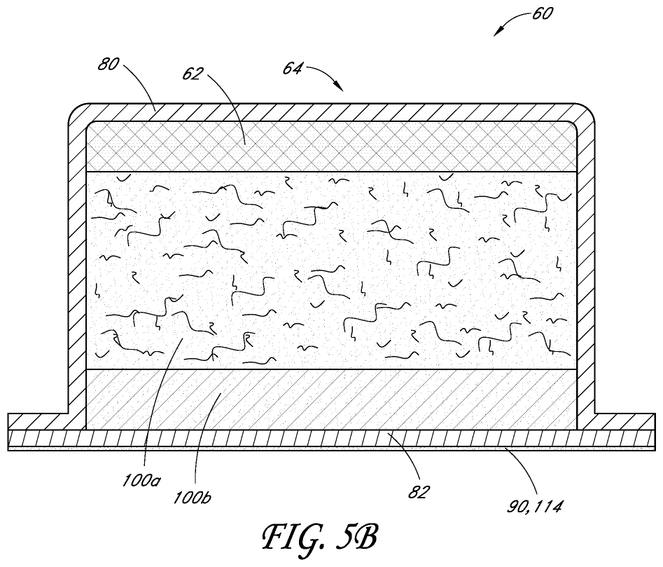

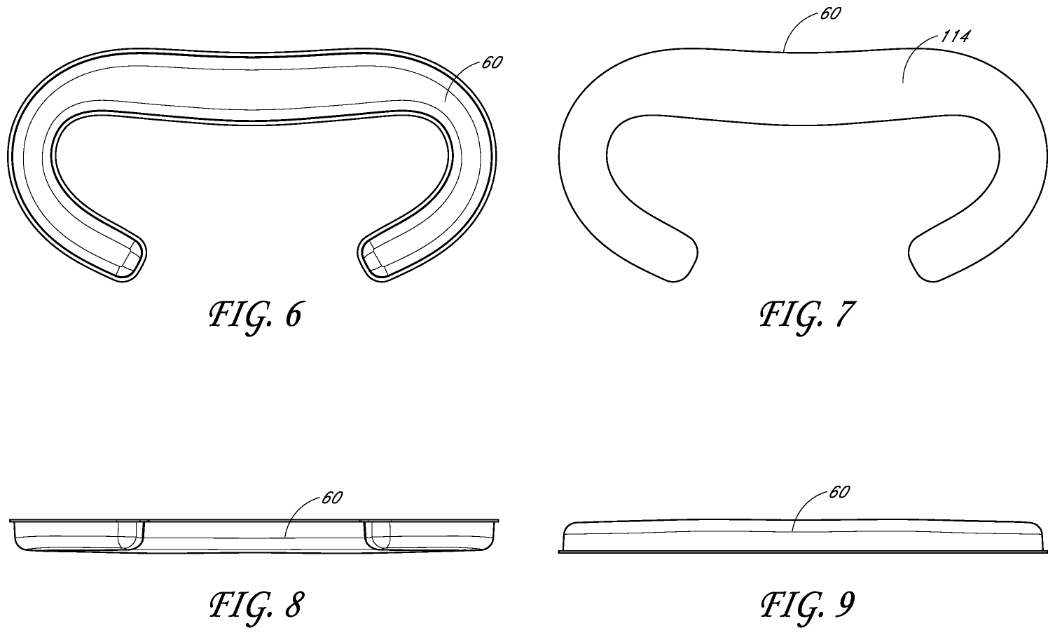

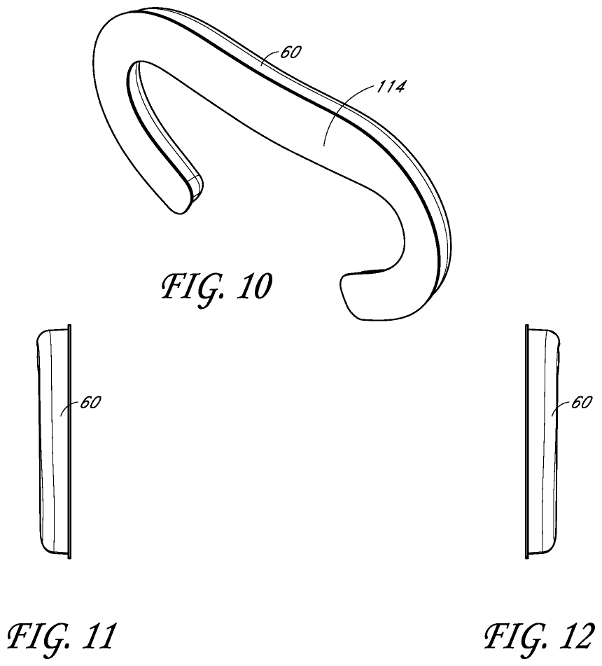

With reference to FIG. 5a, in one arrangement, the illustrated facial interface 60 includes a cooling portion or cooling layer 62 that is constructed from or comprises a cooling agent, such as but not limited to a gel or liquid. The chemical structure of this cooling agent can be configured such that it does not freeze when placed in a cold environment (e.g., a refrigerator or freezer) but maintains its pliable liquid or gel form. Such an arrangement allows the facial interface 60 to provide comfortable cooling to the user for a period of time. As described above, the cooling layer 62 can be reusable in which it is chargeable in a cold environment, such as refrigerator or freezer. Once removed from the cold environment, the cooling layer 62 provides the facial interface 60 with an ability to provide a cooling effect to a user for a period of time before needing recharging. In some configurations, the cooling layer 62 is configured to provide a cooling effect to the user of the facial interface 60 for at least 10-15 minutes after removal from the cold environment when the facial interface 60 has been in the cold environment for at least one hour. In some configurations, the cooling layer 62 and/or the associated facial interface 60 is configured to remain below room temperature for at least 10-15 minutes after removal from the cold environment when the facial interface 60 has been in the cold environment for at least one hour. However, the facial interface 60 will stay cold longer than the 10-15 minute period of time if not applied to the warm body of a user. For example, in some configurations, the cooling layer 62 and/or the associated facial interface 60 is configured to remain below room temperature for at least 45 minutes after removal from the cold environment when the facial interface 60 has been in the cold environment for at least 15-30 minutes. In some configurations, the cooling layer 62 and/or the associated facial interface 60 is configured to remain below room temperature for at least 45 minutes after removal from the cold environment when the facial interface 60 has been in the cold environment for at least one hour. In some configurations, the cooling layer 62 and/or the associated facial interface 60 is configured to remain below room temperature for at least 60 minutes after removal from the cold environment when the facial interface 60 has been in the cold environment for at least one hour. Room temperature can be between about twenty (20) and about twenty-five (25) degrees Celsius.

In the illustrated arrangement of FIG. 5a, the cooling layer 62 forms a central or innermost layer of the facial interface 60. The cooling layer 62 can form a core of the facial interface 60. The cooling layer 62 can form a majority of the cross-sectional area of the facial interface 60, the volume of the facial interface 60, and/or the mass of the facial interface 60. The cooling layer 62 can include a bottom surface 70, a pair of opposing side surfaces 72, 74, and a top surface 76. In the illustrated arrangement, the bottom surface 70 and the opposing side surfaces 72, 74 are flat or substantially flat. These surfaces 70, 72, 74 can be described as linear or straight in cross-section. In the illustrated arrangement, the top surface 76 is curved. The flat bottom surface 70 can facilitate connection to the frame 50 and the curved top surface 76 can facilitate a comfortable experience by the user.

The illustrated facial interface 60 includes an external structure, which can be an external layer or outer layer 64. The outer layer 64 can define a portion or an entirety of the surface that contacts the skin of the user's face. The outer layer 64 can be or include one or more suitable materials, such as but not limited to leather, faux leather (e.g., polyurethane leather), polyurethane, natural rubber, synthetic rubber, silicone, fabric, other heat-permeable natural materials, artificial materials, or a mixture of natural and artificial materials may be suitable. Other suitable materials could also be used. The outer layer 64 can be selected for comfort and the ability to permit heat transfer to facilitate the cooling effect of the facial interface 60. leather, faux leather, and. In some configurations, the outer layer 64 has a suitable thickness to efficiently transfer heat away from the user's face. Preferably, the outer layer 64 does not become solid or maintains conformability at zero (0) degrees Celsius. The outer layer 64 can be configured to remain comfortable to the user's skin at temperatures ranging from zero (0) to forty (40) degrees Celsius. The outer layer 64 can be configured to not cause frostbite or discomfort when removed from the cold environment at zero (0) degrees Celsius and placed on the user's skin moments later. The outer layer 64 can be the thinnest layer of the facial interface 60.

The outer layer 64 can include a first portion or an upper portion 80 and a second portion or a lower portion 82. The upper portion 80 can generally cover the top surface 76. In some configurations, the upper portion 80 can also cover the side surfaces 72, 74. The lower portion 82 can generally cover the bottom surface 70. The upper portion 80 and the lower portion 82 can be formed as separate pieces and joined together. In other configurations, the upper portion 80 and the lower portion 82 can be formed as a single piece or unitary structure.

In the illustrated arrangement, the upper portion 80 and the lower portion 82 are joined together at a seam 84 that extends along a periphery of the facial interface 60. The illustrated seam 84 is located at a frame-contacting surface 90 of the outer layer 64 and may form a portion of the frame-contacting surface 90. The seam 84 extends laterally outward from the facial interface 60. Such an arrangement can result in a flat or substantially flat frame-contacting surface 90 that includes the lower portion 82 and the seam 84 on each side of the facial interface 60.

The seam 84 can be configured to absorb forces applied to the facial interface 60 tending to separate the layers of the seam 84 (e.g., the upper portion 80 and the lower portion 82) under normal use conditions. Such forces can be incurred when the upper portion 80 is grasped to remove the facial interface 60 from the frame 50. A connection between the facial interface 60 and the frame 50 can apply an opposing force to the facial interface 60 through the lower portion 82. Thus, a force can be applied to the seam 84 when the facial interface 60 is removed from the frame 50. In some configurations, the facial interface 60 may be configured for regular removal from the frame to allow recharging of the cooling layer 62. Such recharging may include replacement with a second facial interface 60 while the first facial interface 60 is recharged. In such a configuration, with frequent removal of the facial interface 60, the strength and durability requirements of the seam 84 are significantly greater than a facial interface that is kept in place and not intended to be frequently removed. To provide sufficient strength and durability, the seam 84 can define a lateral width 86 of at least about one (1) millimeter (mm) or at least about three (3) mm. In the illustrated arrangement, the lateral width 86 is about two (2) mm. Such an arrangement has been discovered to provide a suitable joined area of the seam 84 to provide suitable strength and durability. The seam 84 can be formed by a heat-sealing process, a radiofrequency (RF) welding process, another suitable welding process, adhesives, or stitching, for example.

As described herein, the facial interface 60 is utilized as a cushion or interface between the VR goggle 30 and the user's face, and therefore contacts the user's facial skin. Portions of the face can be sensitive to pressure. To provide a sufficient or desirable level of comfort, the facial interface 60 can include optional additional layers to increase comfort or to provide the facial interface 60 with other desirable properties. In the illustrated arrangement, the facial interface 60 includes an intermediate layer 100 between the cooling layer 62 and the outer layer 64. In the illustrated configuration, the intermediate layer 100 completely surrounds the cooling layer 62. However, in other configurations, the intermediate layer 100 may only partially surround the cooling layer 62. For example, the intermediate layer 100 may be positioned only on the user-side or only opposite the user-side of the cooling layer 62. In one configuration, the intermediate layer 100 may be positioned only on the side of the facial interface 60 closest to the frame 50. The intermediate layer 100 may not be provided between the cooling layer 62 and the user-contacting surface of the facial interface 60.

The intermediate layer 100 can be constructed from or can comprise a cushioning material, such as a foam material. Thus, the intermediate layer 100 can be referred to herein as a foam layer for convenience. However, references to a foam layer in the disclosure are intended to refer to other types of cushioning materials unless otherwise indicated explicitly or by context. The foam layer 100 can be constructed from a suitable foam material that permits a suitable amount of heat transfer such that the facial interface 60 provides a suitable level of cooling to the user. For example, a suitable foam material can be an open cell foam or a memory foam material. Such a foam material can be a polyurethane-based foam, such as a viscoelastic polyurethane foam. Other suitable foams can also be used. In addition to the type of foam material utilized for the foam layer 100, a thickness 102 of the foam layer 100 may be selected to provide a suitable amount of comfort while also facilitating heat transfer through the foam layer 100. A suitable thickness of the foam layer 100 can be between about one (1) mm and about five (5) mm. In the illustrated arrangement, the foam layer 100 has a thickness of about two (2) mm. Materials other than foam can be used that helps the facial interface 60 to contour to the shape of the user's specific facial geometry. That is, foam layer 100 can be conformable, and can increase the conformability of the facial interface 60 in comparison to a version with only the cooling layer 62 and the outer layer 64. In some configurations, the foam layer 100 can the cooling layer 62 can be partially or entirely integrated with one another. For example, the foam material of the foam layer 100 can be impregnated with a cooling agent, such as a cooling liquid or gel of the type disclosed herein with respect to the cooling layer 62.

The facial interface 60 is utilized as a cushion or interface between the VR goggle 30 and the user's face. To provide a sufficient or desirable level of comfort, the facial interface 60 can have a sufficient overall thickness 106 to provide a suitable cross-sectional area or volume of the cooling layer 62, a suitable thickness 102 of the foam layer 100, and/or a suitable thickness of the outer layer 64. In some configurations, the overall thickness 106 can be between about five (5) mm and about fifteen (15) mm. In some configurations, the overall thickness 106 can be between about ten (10) mm and about twelve (12) mm. The thickness may vary depending on the particular VR goggle 30 for which the facial interface 60 is designed for use.

As discussed above, in some configurations, the facial interface 60 is easily separable from the frame 50. Such a configuration can permit the user to replace the facial interface 60 with a fresh facial interface 60 once the effectiveness of the facial interface 60 being used has been reduced. In some configurations, several facial interfaces 60 can be sold as a kit to allow one to be used while one or more others are being cooled or recharged. In some configurations, the facial interface 60 is configured to permit at least one-hundred (100) cycles of attachment and removal without significant risk of failure. In some configurations, the frame 50 is sold as part of a kit along with one or more facial interfaces 60.

The facial interface 60 can incorporate a connector 110 to attach the facial interface 60 to the hard plastic frame 50 (or directly to the VR goggle 30). The connector 110 can be a removable connector. The connector 110 can be of any suitable type, such as adhesive (e.g., permanent, removable, and/or reusable adhesive) or mechanical fasteners (e.g., fasteners, snap-fit connections, hook-and-loop fasteners, or magnetic fasteners). In some configurations, the facial interface 60 may simply be placed between the user's face and the hard plastic frame 50 or between the user's face and the VR goggle 30. In some such configurations, other positional means may be provided to keep the facial interface 60 in place while the VR goggle 30 is being used. For example, the facial interface 60 and/or frame 50 could include a lip extending along a portion or an entirety of an inner and/or an outer perimeter to help hold the facial interface 60 in place during use but allow easy removal. Such a positional arrangement could be used alone or in combination with the connector 110. In some configurations, the connector 110 is configured to have a removal force that is less than a removal force of the frame 50 from the VR goggle 30 such that the facial interface 60 can be removed from the frame 50 without causing removal of the frame 50 from the VR goggle 30. In some configurations, the facial interface 60 is permanently attached to the frame 50.

In the illustrated arrangement, the connector 110 is a hook and loop fastener having a hook portion 112 and a loop portion 114. The hook portion 112 is provided on one of the facial interface 60 and the frame 50 and the loop portion 114 is provided on the other of the facial interface 60 and the frame 50. The hook and loop fastener can have a suitable surface area to generate a suitable level of holding power for the facial interface 60 such that the facial interface 60 is held in place on the frame 50 but can be removed when desired.

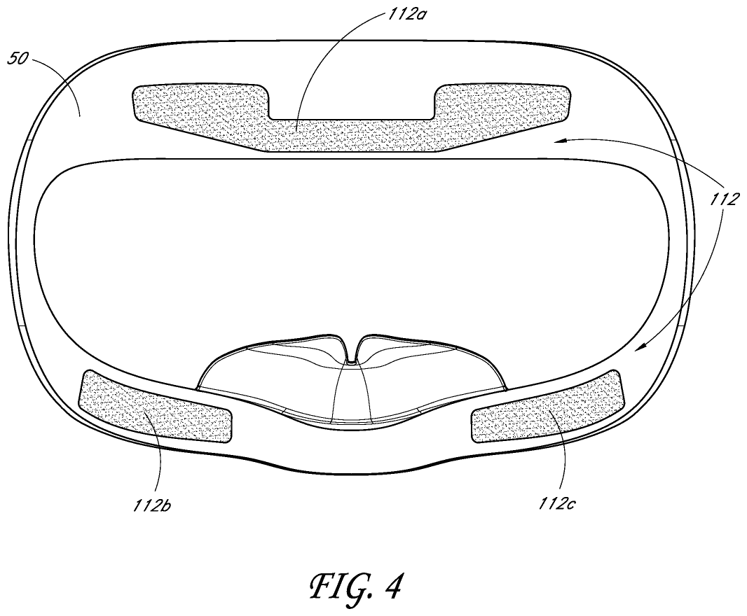

In the illustrated arrangement, as shown in FIG. 4, for example, the hook portion 112 is provided on the frame 50. The hook portion 112 can be provided as a plurality of discrete locations 112a, 112b, 112c. The locations 112a, 112b, 112c can be distributed between an upper portion and a lower portion of the frame 50. In the illustrated arrangement, the location 112a is located on the upper portion of the frame 50 that corresponds to the user's forehead. The locations 112b, 112c are provided on the lower portion of the frame 50 on either side of a nose portion of the frame 50. The locations 112b, 112c can correspond to the user's cheeks.

In the illustrated arrangement, the loop portion 114 is provided on the facial interface 60. In some configurations, the loop portion 114 is provided on or defines at least a portion of the frame-contacting surface 90. The loop portion 114 can be provided on or define an entirety or substantial entirety of the frame-contacting surface 90. The loop portion 114 can be provided by the lower portion 82 of the outer layer 64 or can be attached to the outer layer 64.

FIG. 5b illustrates an alternative facial interface 60 that has a different arrangement of the internal structures in comparison to the facial interface 60 of FIG. 5a. The facial interface 60 of FIG. 5b is described in the context of the differences relative to the facial interface of FIG. 5a. Accordingly, features or details not discussed with respect to FIG. 5b can be the same as or similar to the corresponding feature or detail of FIG. 5a, or can be of another suitable arrangement.

As with the prior version of the facial interface 60, the illustrated facial interface 60 of FIG. 5b includes an outer layer 64, which can include a first portion or an upper portion 80 and a second portion or a lower portion 82. The upper portion 80 and the lower portion 82 can be formed as separate pieces and joined together. In other configurations, the upper portion 80 and the lower portion 82 can be formed as a single piece or unitary structure. In the illustrated arrangement, the upper portion 80 and the lower portion 82 are joined together at a seam 84 that extends along a periphery of the facial interface 60.

The facial interface 60 includes a cooling layer 62 that is constructed from or comprises a cooling agent, such as any of those described herein. In the illustrated arrangement, the cooling layer 62 is located closes to the user-contacting surface of the facial interface 60. The cooling layer 62 can have a thickness of at least about three (3) mm. In some configurations, the cooling layer 62 has a thickness of about five (5) mm.

The facial interface 60 can include optional additional layers to increase comfort or to provide the facial interface 60 with other desirable properties. In the illustrated arrangement, the facial interface 60 includes one or more foam layers 100 constructed from suitable foam material(s), such as those described herein. In the illustrated arrangement, the facial interface 60 includes two foam layers 100a, 100b. The first foam layer 100a can be of a first foam type or have a first set of characteristics and the second foam layer 100b can be of a second foam type or have a second set of characteristics that are different from those of the first foam layer 100a. In some configurations, the first foam layer 100a can be a memory foam, such as one of those described herein. In some configurations, the second foam layer 100b can be a different type of foam, such as an EVA foam, for example and without limitation. Moreover, in some configurations, the second foam layer 100b can be omitted. The first foam layer 100a can be located closer to the user-contacting surface of the facial interface 60 relative to the second foam layer 100b.

If both the first foam layer 100a and the second foam layer 100b are provided, they can be of the same thickness or preferably of different thicknesses. In some configurations, the first foam layer 100a is thicker than the second foam layer 100b. In some configurations, a suitable thickness of the first foam layer 100a can be between about five (5) mm and about fifteen (15) mm, or between about eight (8) mm and about twelve (12) mm. In the illustrated arrangement, the first foam layer 100a has a thickness of about ten (10) mm. In some configurations, a suitable thickness of the second foam layer 100b can be between about one (1) mm and about five (5) mm, or between about one (1) mm and about three (3) mm. In the illustrated arrangement, the second foam layer 100b has a thickness of about two (2) mm. In some configurations, the thickness of the foam materials described herein can be in an uncompressed condition and the actual thickness of the foam layer once integrated into the facial interface 60 can be less than the uncompressed thickness. The first foam layer 100a and the second foam layer 100b, or a combination thereof, can form a majority of the cross-sectional area of the facial interface 60, the volume of the facial interface 60, and/or the mass of the facial interface 60. In some configurations, the first foam layer 100a and the second foam layer 100b, or a combination thereof, can form about two-thirds or at least about two-thirds of the cross-sectional area of the facial interface 60, the volume of the facial interface 60, and/or the mass of the facial interface 60.

With other types of VR goggles 30, the shape of the frame 50 may be different, which may result in a different shape of the facial interface 60. For example, the facial interface 60 may be located only along the user's forehead. The location 112a on the upper portion of the frame 50 may overlap a portion or an entirety of the locations 112b, 112c on the lower portion of the frame in a vertical direction. The general shape of the facial interface 60 and/or the frame 50 may change depending on the shape of the VR goggle 30 and/or the specific size and shape of the user. The shape of the facial interface 60 and/or the frame 50 is not necessarily material to the invention, as the shape may change and evolve over time or to suit a specific type or brand of VR goggle 30 (or other type of goggle). However, the concept of providing a cooling agent or cooling material may be incorporated in a facial interface 60 of a variety of different shapes. A general shape has been provided as a “generic” to better provide an idea of the facial interface 60. However, the utility of incorporating a cooling layer 62 into the facial interface 60 of a VR goggle 30 can be incorporated into many different shapes and designs such as a smaller or bigger size, an open or closed loop, or any other design that fits the needs of the user.

One or more of the facial interfaces 60 described herein provide an advantageous level of performance in comparison to the prior art. Several characteristics can be considered in the performance of the facial interface 60. For example, the facial interface 60 can be configured to be able to form to the shape of the user's face for enhanced comfort as well as to block most of the external light from leaking through any gaps between the facial interface 60 and therefore tarnish the immersive experience associated with wearing VR goggle 30. The foam layer 100 can be a form-fitting material that can shape itself to the contours of the user's face allowing for an optimal fit to ensure comfort. The form-fitting feature of the foam layer 100 can also facilitate the blocking of external light from entering the viewing space between the user's eyes and the goggle 30, ensuring a sufficient level of darkness in the internal space, and allowing for the optimum immersive space. The foam material can be selected to ensure it can withstand temperature ranges of about minus five (−5) and thirty-five (35) degrees Celsius repeatedly while retaining a usable portion of its physical properties or without deteriorate past the usable range. The usable range is defined as the range in which the device retains its main functions of allowing assembly onto the VR goggle 30, cooling down and remain cool for at least 10-15 mins, comfortably being worn in temperatures between zero (0) and thirty-five (35) degrees Celsius for at least 10-15 minutes, block a sufficient amount or most external light from entering the VR goggle 30 viewing space. As described above, the foam material should remain flexible within its operating temperatures of between zero (0) and thirty-five (35) degrees Celsius, allowing for easy contouring to the user's face.

### CONCLUSION

It should be emphasized that many variations and modifications may be made to the herein-described embodiments, the elements of which are to be understood as being among other acceptable examples. All such modifications and variations are intended to be included herein within the scope of this disclosure and protected by the following claims. Moreover, any of the steps described herein can be performed simultaneously or in an order different from the steps as ordered herein. Moreover, as should be apparent, the features and attributes of the specific embodiments disclosed herein may be combined in different ways to form additional embodiments, all of which fall within the scope of the present disclosure.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

Moreover, the following terminology may have been used herein. The singular forms “a,” “an,” and “the” include plural referents unless the context clearly dictates otherwise. Thus, for example, reference to an item includes reference to one or more items. The term “ones” refers to one, two, or more, and generally applies to the selection of some or all of a quantity. The term “plurality” refers to two or more of an item. The term “about” or “approximately” means that quantities, dimensions, sizes, formulations, parameters, shapes and other characteristics need not be exact, but may be approximated and/or larger or smaller, as desired, reflecting acceptable tolerances, conversion factors, rounding off, measurement error and the like and other factors known to those of skill in the art. The term “substantially” means that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

What is claimed is:

1. A facial interface for a goggle, comprising:
a body defining a user-contacting surface configured to contact the face of a user;
wherein the body comprises a cooling agent configured to absorb heat from the user along the user-contacting surface for a period of time; and
wherein the facial interface is configured to be positioned between the goggle and the face of the user.

2. The facial interface for a goggle of claim 1, wherein the period of time is at least ten (10) minutes.

3. The facial interface for a goggle of claim 1, in combination with a frame configured to support the facial interface.

4. The facial interface for a goggle of claim 3, wherein the frame is removably connectable to the goggle.

5. The facial interface for a goggle of claim 1, wherein the cooling agent is contained in a discrete layer.

6. The facial interface for a goggle of claim 1, further comprising a cushioning layer.

7. The facial interface for a goggle of claim 6, wherein the cooling agent is contained in a discrete layer, and the cooling layer is positioned closer to the user-contacting surface than the cushioning layer.

8. A facial interface for a goggle, comprising:
a cooling layer comprising a cooling substance configured to be cooled in a cold environment and to absorb heat from a user of the facial interface for a period of time after removal from the cold environment; and
an outer layer comprising a user-contacting surface configured to contact a face of the user;
wherein the facial interface is configured to be positioned between the goggle and the face of the user.

9. The facial interface for a goggle of claim 8, wherein the facial interface comprises a closed loop or an open loop.

10. The facial interface for a goggle of claim 8, further comprising at least one cushioning layer.

11. The facial interface for a goggle of claim 10, wherein the cooling layer is located closer to the user-contacting surface than the cushioning layer.

12. The facial interface for a goggle of claim 10, wherein the at least one cushioning layer comprises a first cushioning layer and a second cushioning layer.

13. The facial interface for a goggle of claim 8, wherein the period of time is at least ten (10) minutes.

14. The facial interface for a goggle of claim 8, wherein the outer layer comprises a first portion and a second portion joined at a seam.

15. The facial interface for a goggle of claim 14, wherein the seam comprises a minimum width of at least about one (1) mm.

16. The facial interface for a goggle of claim 8, wherein at least a portion of the facial interface defines an overall thickness of at least five (5) mm.

17. The facial interface for a goggle of claim 8, wherein the cooling layer comprises a majority of a volume of the facial interface.

18. The facial interface for a goggle of claim 8, in combination with a frame configured to support the facial interface.

19. The combination of claim 18, further comprising a connector configured to connect the facial interface to the frame.

20. The facial interface for a goggle of claim 19, wherein the connector comprises a hook-and-loop fastener.
